(19) United States
(12) Patent Application Publication
(10) Pub. No.: US 2024/0268194 A1
(43) Pub. Date: Aug. 8, 2024

(54) DISPLAY PANELS AND DISPLAY TERMINALS

(71) Applicant: Shenzhen China Star Optoelectronics Semiconductor Display Technology Co., Ltd., Shenzhen (CN)

(72) Inventor: Kaikai LI, Shenzhen (CN)

(73) Assignee: Shenzhen China Star Optoelectronics Semiconductor Display Technology Co., Ltd., Shenzhen (CN)

(21) Appl. No.: 18/533,278

(22) Filed: Dec. 8, 2023

(30) Foreign Application Priority Data
Feb. 3, 2023 (CN) 202310131475.3

(51) Int. Cl. H10K 59/80

(52) U.S. Cl. CPC H10K 59/873

(57) ABSTRACT

Display terminals and display panels are provided. The display panel includes a substrate and at least one retaining wall. The retaining wall is disposed on the substrate and outside a display area of the display panel, and surrounds the display area. The retaining wall includes a first retaining wall layer and a second retaining wall layer stacked on the first retaining wall layer and disposed on a side of the first retaining wall away from the substrate. An area of an orthographic projection of the second retaining wall layer on the substrate is less than an area of an orthographic projection of the first retaining wall layer on the substrate, and a horizontal distance between a boundary of the second retaining wall layer away from the display area and a boundary of the first retaining wall layer away from the display area is greater than a first threshold.

### CROSS-REFERENCE TO RELATED APPLICATION

This application claims priority to Chinese Patent Application No. 202310131475.3, filed on Feb. 3, 2023, the disclosure of which is incorporated herein by reference in its entirety.

### TECHNICAL FIELD

The present disclosure relates to the field of display technologies, and in particular, to display panels and display terminals.

### BACKGROUND

When manufacturing a display panel, such as an OLED display panel, a Mini-LED display panels, etc., an encapsulation layer needs to be provided on a display layer of the display panel to prevent water and oxygen from intruding into the display panel. Because an organic encapsulation layer of the encapsulation layer is fluid, in order to limit a range of the organic encapsulation layer, in related art, a retaining wall is generally arranged around a display area of the display panel to block the organic encapsulation layer.

Since a material of the retaining wall has leveling properties, a middle part thereof easily flows to an edge part, making it difficult to increase a height of the retaining wall. When the height of the retaining wall is insufficient, the organic encapsulation layer overflows away from the display area, causing encapsulation failure.

### SUMMARY

In view of above, display panels are provided according to embodiments of the present disclosure. The display panel includes a substrate and at least one retaining wall disposed on the substrate; the retaining wall is disposed on the substrate and outside a display area of the display panel, and surrounds the display area. The retaining wall includes a first retaining wall layer and a second retaining wall layer stacked on the first retaining wall layer and disposed on a side of the first retaining wall away from the substrate. An area of an orthographic projection of the second retaining wall layer on the substrate is less than an area of an orthographic projection of the first retaining wall layer on the substrate, and a horizontal distance between a boundary of the second retaining wall layer away from the display area and a boundary of the first retaining wall layer away from the display area is greater than a first threshold.

Display terminals are also provided according to embodiments of the present disclosure. The display terminal includes the above-mentioned display panel.

### BRIEF DESCRIPTION OF THE DRAWINGS

Technical solutions and other beneficial effects of the present disclosure will be apparent through a detailed description of specific embodiments of the present disclosure in conjunction with the accompanying drawings.

FIG. 1 is a schematic top view of a display panel provided by the present disclosure.

FIG. 2 is a schematic view of a first cross-sectional structure at a CC section in FIG. 1.

FIG. 3 is a schematic view of a second cross-sectional structure at the CC section in FIG. 1.

FIG. 4 is a schematic view of a third cross-sectional structure at the CC section in FIG. 1.

FIG. 5 is a schematic view of a fourth cross-sectional structure at the CC section in FIG. 1.

FIG. 6 is a schematic cross-sectional structural view of a display panel of the present disclosure.

FIG. 7 is a schematic cross-sectional structural view of another display panel of the present disclosure.

### DETAILED DESCRIPTION

The technical solutions in the embodiments of the present disclosure will be clearly and completely described below with reference to the accompanying drawings. Obviously, the described embodiments are only some of the embodiments of the present disclosure, but not all of the embodiments. Based on the embodiments in the present disclosure, all other embodiments obtained by those skilled in the art without making creative efforts fall within the protection scope of the present disclosure. In addition, it should be understood that the specific embodiments described here are only used to illustrate and explain the application, and are not used to limit the application. In the present disclosure, unless otherwise specified, orientational terms used such as “upper” and “lower” usually refer to the upper and lower positions of the device in actual use or working conditions, specifically orientations in the drawings. The terms “inside” and “outside” refer to the outlines of the device.

Since the material of the retaining wall has leveling properties, the middle part thereof easily flows to the edge part, making it difficult to increase the height of the retaining wall. When the height of the retaining wall is insufficient, the organic encapsulation layer overflows away from the display area, causing encapsulation failure. Therefore, there is an urgent need to provide display panels to solve the above technical problem. The present disclosure proposes following solutions aiming at the above technical problem.

The present disclosure provides display panels 100. The display panel 100 includes a substrate 10 and a retaining wall 20 disposed on the substrate 10. The retaining wall 20 is located outside a display area AA of the display panel 100 and surrounds the display area AA. The retaining wall 20 includes a first retaining wall layer 21 and a second retaining wall layer 22 stacked on the first retaining wall layer 21. The second retaining wall layer 22 is disposed on a side of the first retaining wall layer 21 away from the substrate 10. An area of an orthographic projection of the second retaining wall layer 22 on the substrate 10 is less than an area of an orthographic projection of the first retaining wall layer 21 on the substrate 10, and a horizontal distance between a boundary of the second retaining wall layer 22 away from the display area AA and a boundary of the first retaining wall layer 21 away from the display area AA is greater than a first threshold.

In the present disclosure, by arranging the horizontal distance between the boundary of the second retaining wall layer 22 away from the display area AA and the boundary of the first retaining wall layer 21 away from the display area AA to be greater than the first threshold, when manufacturing the second retaining wall layer 22, the boundary of the second retaining wall layer 22 away from the display area AA is either located in a flat area, i.e. a middle area, of the first retaining wall layer 21 or in an area corresponding to a groove 210 of the first retaining wall layer 21, so it is not easy for the second retaining wall layer 22 to flow away from the display area AA, which avoids thickness reduction of the second retaining wall layer 22 caused by diffusion, thereby increasing a height of the retaining wall 20.

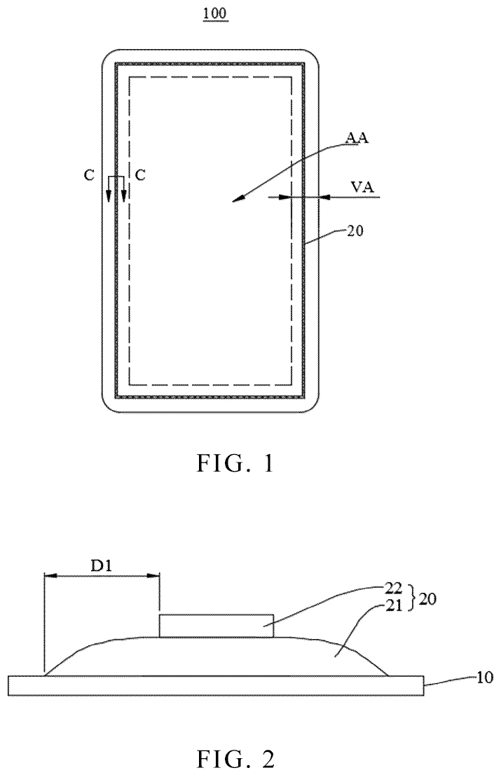

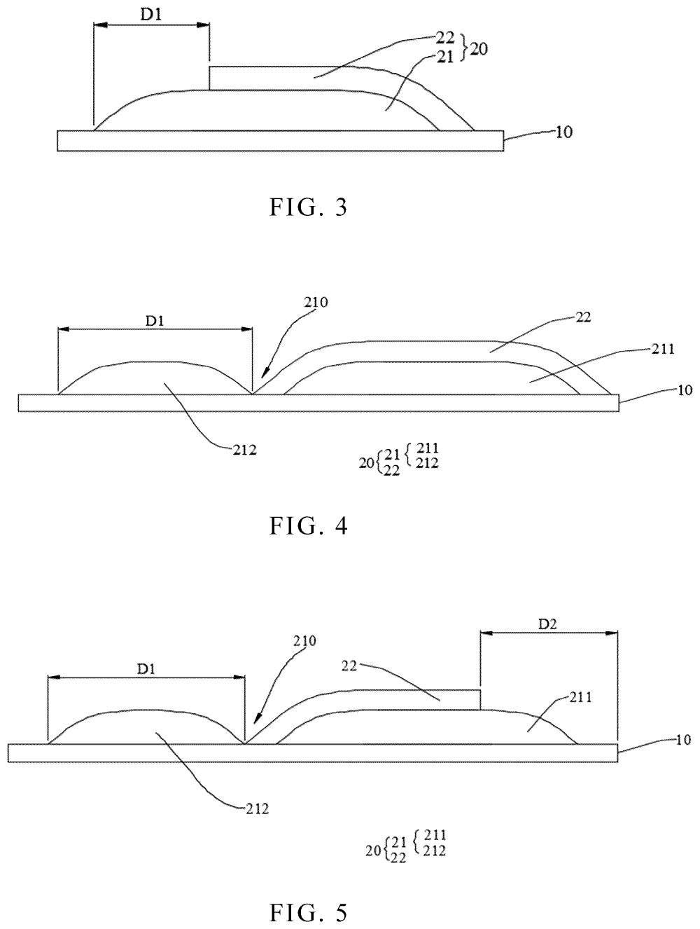

Referring to FIG. 1 to FIG. 5, FIG. 1 is a schematic top view of the display panel 100 according to an embodiment of the present disclosure, FIG. 2 is a schematic view of a first cross-sectional structure at a CC section in FIG. 1, FIG. 3 is a schematic view of a second cross-sectional structure at the CC section in FIG. 1, FIG. 4 is a schematic view of a third cross-sectional structure at the CC section in FIG. 1, and FIG. 5 is a schematic view of a fourth cross-sectional structure at the CC section in FIG. 1.

It should be noted that in the present disclosure, a thickness of a component a refers to a dimension in a direction perpendicular to the substrate 10, and a width of a component refers to a dimension in a direction parallel to the substrate 10 in the cross-sectional view of the retaining wall 20. For example, in FIG. 2 to FIG. 5, a width of the retaining wall 20 refers to a dimension of the retaining wall 20 in a horizontal direction. The boundaries of the retaining wall 20 refer to a closest end of the retaining wall 20 close to the display area AA and a farthest end of the retaining wall 20 away from the display area AA in the cross-sectional view of the retaining wall 20.

As illustrated in FIG. 1, the display panel 100 includes a display area AA located in the middle and a non-display area VA surrounding the display area AA. The retaining wall 20 is disposed outside the display area AA, surrounds the display area AA, and is a closed loop.

As illustrated in FIG. 2 to FIG. 5, the retaining wall 20 is disposed on the substrate 10. The substrate 10 may be a flexible substrate, such as polyimide, or the substrate 10 may be a rigid substrate, such as glass. The retaining wall 20 includes the first retaining wall layer 21 disposed on the substrate 10 and the second retaining wall layer 22 disposed on the first retaining wall layer 21. The area of the orthogonal projection of the second retaining wall layer 22 on the substrate 10 is less than the area of the orthographic projection of the first retaining wall layer 21 on the substrate 10. That is, the second retaining wall layer 22 does not completely cover an upper surface of the first retaining wall layer 21.

In an embodiment as illustrated in FIG. 2, the second retaining wall layer 22 is only provided in a middle area of the first retaining wall layer 21. Since the horizontal distance D1 between the boundary of the second retaining wall layer 22 away from the display area AA and the boundary of the first retaining wall layer 21 away from the display area AA is greater than the first threshold, so that the boundary of the second retaining wall layer 22 away from the display area AA is located at a position of the first retaining wall layer 21 close to the middle area, and the position of the first retaining wall layer 21 close to the middle area has a surface close to flat. Therefore, when manufacturing the second retaining wall layer 22, during a baking process, an end of the second retaining wall layer 22 far away from the display area AA is not easy to flow away from the display area AA, thus a thickness of the second retaining wall layer 22 may be increased.

In an embodiment as illustrated in FIG. 3, the second retaining wall layer 22 only covers part of a surface of the first retaining wall layer 21 close to the display area AA. The boundary of the second retaining wall layer 22 away from the display area AA is located in the middle area of the first retaining wall layer 21. Similar to the embodiment as illustrated in FIG. 2, when manufacturing the second retaining wall layer 22, during the baking process, the end of the second retaining wall layer 22 away from the display area AA is not easy to flow in a direction away from the display area AA. Therefore, the thickness of the second retaining wall layer 22 may be increased.

In the embodiments as illustrated in FIG. 4 and FIG. 5, the second retaining wall layer 22 only covers part of a surface of the first retaining wall layer 21 close to the display area AA, and the boundary of the second retaining wall layer 22 away from the display area AA is located in a groove 210 of the first retaining wall layer 21, in this way, the horizontal distance D1 between the boundary of the second retaining wall layer 22 away from the display area AA and the boundary of the first retaining wall layer 21 away from the display area AA is greater than the first threshold. Thus, when manufacturing the second retaining wall layer 22, during the baking process, the end of the second retaining wall layer 22 away from the display area AA is not easy to flow in a direction away from the display area AA. Therefore, the thickness of the second retaining wall layer 22 may be increased.

In some embodiments, a material of the first retaining wall layer 21 may be an organic photoresist, and a material of the second retaining wall layer 22 may be an organic material. The first retaining wall layer 21 and the second retaining wall layer 22 may be manufactured sequentially through conventional processes in the field. For example, a material layer of the first retaining wall 20 is first formed, and then a photoresist is coated, a photomask is adopted to expose and develop, and then the first retaining wall layer 21 is cured by baking. Then, a material layer of the second retaining wall layer 22 is formed on the first retaining wall layer 21, a photoresist is coated, and a photomask is adopted to expose and develop, and then the second retaining wall layer 22 is cured by baking. Each of the first retaining wall layer 21 and the second retaining wall layer 22 may be made of the same material and/or produced in the same process as some film layers of the display panel 100 in the display area AA, thereby simplifying the manufacturing process of the display panel 100 and reducing production costs. For example, the first retaining wall layer 21 may be made of the same material as a planarization layer of the display panel 100, and the second retaining wall layer 22 may be made of the same material as a pixel definition layer of the display panel 100. Furthermore, the first retaining wall layer 21 may be manufactured in the same process as the planarization layer, and the second retaining wall layer 22 may be manufactured in the same process as the pixel definition layer, thereby simplifying the manufacturing process of the display panel 100 and reducing the production costs. The materials of the first retaining wall layer 21 and the second retaining wall layer 22 are not limited in the present disclosure.

In some embodiments, as illustrated in FIG. 2 to FIG. 5, since a width of the first retaining wall layer 21 is greater than a width of the second retaining wall layer 22, for materials with fluidity, when the width increases, its thickness is easy to increase. Therefore, the thickness of the first retaining wall layer 21 may be greater than the thickness of the second retaining wall layer 22. That is, in the direction perpendicular to the substrate 10, a maximum thickness of the first retaining wall layer 21 is greater than a maximum thickness of the second retaining wall layer 22, so that it is easier to increase the thickness of the retaining wall 20.

In the present disclosure, the display panel 100 may be an OLED display panel, a Mini-LED display panel, a Micro-LED, or other display panel, which is not limited in the present disclosure.

The technical solutions of the present disclosure will now be described with reference to specific embodiments.

Referring to FIG. 2, in this embodiment, the first retaining wall layer 21 is continuously provided in a direction away from the display area AA, and the orthographic projection of the second retaining wall layer 22 on the substrate 10 is located in a middle area of the orthographic projection of the first retaining wall layer 21 on the substrate 10. The middle area refers to an area located in the middle of the first retaining wall layer 21, having a horizontal distance greater than the first threshold from the boundary of the first retaining wall layer 21 close to the display area AA, and having a horizontal distance greater than the first threshold from the boundary of the first retaining wall layer 21 away from the display area AA. In some embodiments, a value of the first threshold may be 8.5 microns, that is, D1 is greater than or equal to 8.5 microns.

Referring to FIG. 3, in this embodiment, the first retaining wall layer 21 is continuously provided in a direction away from the display area AA, and the orthographic projection of the second retaining wall layer 22 on the substrate 10 partially overlaps the orthographic projection of the first retaining wall layer 21 on the substrate 10. The horizontal distance D1 between the boundary of the second retaining wall layer 22 away from the display area AA and the boundary of the first retaining wall layer 21 away from the display area AA is greater than the first threshold. The boundary of the second retaining wall layer 22 close to the display area AA covers the boundary of the first retaining wall layer 21 close to the display area AA. That is to say, an orthographic projection of the boundary of the second retaining wall layer 22 away from the display area AA on the substrate 10 is located in the middle area of the orthographic projection of the first retaining wall layer 21 on the substrate 10, and an orthographic projection of the boundary of the second retaining wall layer 22 close to the display area AA on the substrate 10 is located adjacent to an edge area of the orthographic projection of the first retaining wall layer 21 on the substrate 10.

It should be noted that FIG. 3 only illustrates a condition where the end of the second retaining wall layer 22 close to the display area AA completely covers the end of the first retaining wall layer 21 close to the display area AA. In fact, the boundary of the second retaining wall layer 22 close to the display area AA may be located at any position on a slope of the first retaining wall layer 21 close to the display area AA. The orthographic projection of the boundary of the second retaining wall layer 22 close to the display area AA on the substrate 10 may be located within or outside the orthographic projection of the first retaining wall layer 21 on the substrate 10, or the orthographic projection of the boundary of the second retaining wall layer 22 close to the display area AA on the substrate 10 may overlap with the orthographic projection of the boundary of the first retaining wall layer 21 close to the display area AA on the substrate 10. That is, the present disclosure does not limit the position of the boundary of at the end of the second retaining wall layer 22 near the display area AA.

In the embodiments, referring to FIG. 4 and FIG. 5, the first retaining wall layer 21 is separated into a first retaining wall segment 211 and a second retaining wall segment 212 in a direction away from the display area AA. The second retaining wall segment 212 is located on a side of the first retaining wall segment 211 away from the display area AA, and a groove 210 is formed between the first retaining wall segment 211 and the second retaining wall segment 212. The second retaining wall layer 22 at least partially fills the groove 210. Since the end of the second retaining wall layer 22 away from the display area AA is located in the groove 210, so that the end of the second retaining wall layer 22 away from the display area AA may be blocked by a sidewall of the second retaining wall segment 212, which slows down a flow speed of the second retaining wall layer 22, thereby preventing the second retaining wall layer 22 from spreading outward unrestrictedly, thus preventing the thickness of the second retaining wall layer 22 from being excessively reduced. The width of the groove 210 may be 2 microns, and may be reduced as much as possible to avoid occupying too much area of a frame of the display panel. The width of the groove 210 is not limited in the present disclosure.

The first retaining wall layer 21 may be made by conventional processes in this field. For example, the material layer of the first retaining wall 20 is formed, a photoresist is coated, a photomask is adopted to expose and develop to form a pattern with the groove 210, and then the first retaining wall layer 21 is cured by baking.

As illustrated in FIG. 4 and FIG. 5, the second retaining wall segment 212 may include only one layer of material. A material of the second retaining wall segment 212 may be the same with a material of the first retaining wall segment 211, or the material of the second retaining wall segment 212 may the same with a material of the second retaining wall layer 22. Since there is no need to provide a second layer of material above the second retaining wall segment 212, a width of the second retaining wall segment 212 may be less than or equal to a width of the first retaining wall segment 211, and a thickness of the second retaining wall segment 212 may be less than or equal to a thickness of the first retaining wall segment 211. Thus, an area of an orthographic projection of the second retaining wall segment 212 on the substrate 10 is reduced as much as possible, thereby achieving the effect of a narrow frame. In some embodiments, the width of the second retaining wall segment 212 may range from 20 microns to 40 microns, thereby balancing the area of the orthographic projection of the second retaining wall segment 212 on the display panel 100 and blocking effect of the second retaining wall layer 22.

Optionally, in the embodiment as illustrated in FIG. 4, the end of the second retaining wall layer 22 close to the display area AA covers the first retaining wall segment 211, and the orthographic projection of the first retaining wall segment 211 on the substrate 10 is located within the orthographic projection of the second retaining wall layer 22 on the substrate 10.

Optionally, in the embodiment as illustrated in FIG. 5, the orthographic projection of the second retaining wall layer 22 on the substrate 10 partially overlaps the orthographic projection of the first retaining wall segment 211 on the substrate 10, and a horizontal distance D2 between a boundary of the second retaining wall layer 22 close to the display area AA and a boundary of the first retaining wall segment 211 close to the display area AA is greater than the first threshold. That is, D2 is greater than or equal to 8.5 microns, an orthographic projection of the boundary of the second retaining wall layer 22 close to the display area AA on the substrate 10 is located in a middle area (i.e. a flat area) of the orthographic projection of the first retaining wall segment 211 on the substrate 10, so that a step is formed between the boundary of the second retaining wall layer 22 close to the display area AA and the first retaining wall segment 211, which further improves the blocking effect of the organic encapsulation layer 40 of the display panel 100.

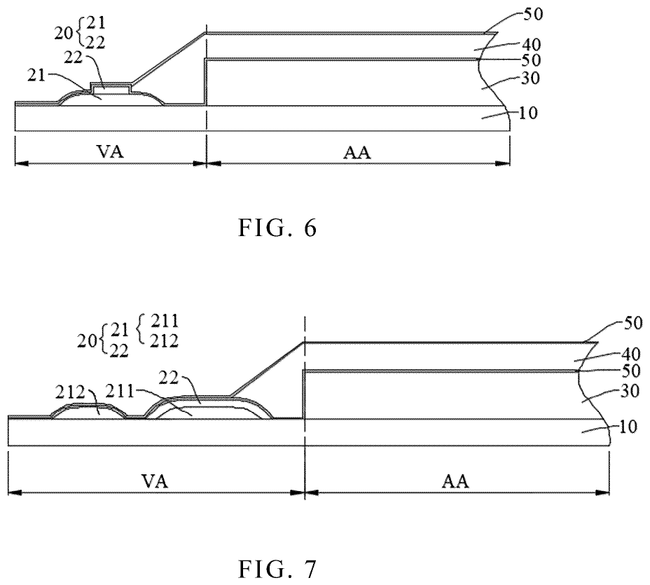

Referring to FIG. 6 and FIG. 7, FIG. 6 is a schematic cross-sectional structural view of the display panel 100 of the present disclosure, and FIG. 7 is a schematic cross-sectional structural view of another display panel 100 of the present disclosure. It should be noted that FIG. 6 and FIG. 7 are partial cross-sectional structures of the display panels 100 of the present disclosure, and do not show complete cross-sectional structures of the display panels 100. In the display panel 100 of the present disclosure, the display panel 100 further includes a display layer 30 provided on the substrate 10 and an organic encapsulation layer 40 stacked on the display layer 30. The display layer 30 is arranged in the display area AA, and the organic encapsulation layer 40 is arranged on a side of the retaining wall 20 close to the display area AA. In the direction perpendicular to the substrate 10, a thickness of an end of the organic encapsulation layer 40 close to the retaining wall 20 is less than the thickness of the retaining wall 20.

The display layer 30 may include a thin film transistor array layer (not shown in the figures), a light-emitting layer, and other film layers (not shown in the figures). The display layer 30 includes a plurality of pixels distributed in an array to realize a display image. The thin film transistor may be a thin film transistor having a top gate structure or a thin film transistor having a bottom gate structure, which is not limited in the present disclosure. An active layer of the thin film transistor may be made of low-temperature polysilicon, metal oxide, etc., which is not limited in the present disclosure.

The organic encapsulation layer 40 may be made of an organic material, and the organic encapsulation layer 40 may be made by ink jet printing (IJP) or other processes. The organic encapsulation layer 40 can improve waterproof and oxygen-proof abilities of the encapsulation layer, and absorb a stress generated when bending or being impacted by external forces.

In some embodiments, the display panel 100 further includes at least one inorganic encapsulation layer 50 stacked and in contact with the organic encapsulation layer 40, thereby further improving the waterproof and oxygen resistance. As illustrated in FIG. 6 and FIG. 7, an upper surface and a lower surface of the organic encapsulation layer 40 are both provided with one inorganic encapsulation layer 50 thereon. The organic encapsulation layer 40 and the inorganic encapsulation layers 50 may be arranged alternately. A thickness of an end of the organic encapsulation layer 40 close to the retaining wall 20 is less than the thickness of the retaining wall 20, thereby preventing the organic encapsulation layer 40 from overflowing.

FIG. 6 illustrates the display panel 100 of the present disclosure, in which the second retaining wall layer 22 is arranged in the middle area of the first retaining wall layer 21. The inorganic encapsulation layer 50 covers an upper surface of the second retaining wall layer 22 of the retaining wall 20 and an end of the first retaining wall layer 21 away from the display area AA. A sum of the thicknesses of the first retaining wall layer 21 and the second retaining wall layer 22 is greater than a height of an end of the organic encapsulation layer 40 close to the retaining wall 20, thereby blocking overflow of the organic encapsulation layer 40.

FIG. 7 illustrates another display panel 100 of the present disclosure in which the retaining wall 20 includes the first retaining wall segment 211 and the second retaining wall segment 212 arranged separately, and the second retaining wall layer 22 covers an upper surface of the first retaining wall segment 211. The inorganic encapsulation layer 50 covers an upper surface of the second retaining wall segment 212 and the end of the second retaining wall layer 22 away from the display area AA. The ends of the first retaining wall segment 211 and the second retaining wall layer 22 close to the display area AA are configured to block the organic encapsulation layer 40.

It should be noted that in the above embodiments, the display panel 100 may include a plurality of retaining walls 20 that are spaced apart to form multiple closed loops surrounding the display area AA, thereby further preventing water and oxygen from intruding into the display panel 100 from sides of the display panel 100.

In some embodiments, the display panel 100 may further include a closed-loop groove disposed in the non-display area VA. The closed-loop groove is located on a side of the retaining wall 20 close to the display area AA and may accommodate part of the organic encapsulation layer 40, which reduces a thickness of a side of the organic encapsulation layer 40 close to the retaining wall 20. At the same time, the closed-loop groove may also reduce a flow speed of an organic material of the organic encapsulation layer 40, which prevents the organic encapsulation layer 40 from overflowing, thereby improving encapsulation effect.

In the above embodiments, a material of the inorganic encapsulation layer 50 may be silicon oxide, silicon nitride, silicon oxynitride, aluminum oxide, etc., but is not limited thereto.

The present disclosure also provides display terminals. The display terminal includes the above-mentioned display panel 100.

In the embodiments, the display terminal may be a mobile phone, a tablet, a TV, a monitor, a laptop, a digital photo frame, a navigator, and any other products or components with display function.

In the above embodiments, each embodiment is described with its own emphasis. For parts that are not described in detail in a certain embodiment, the relevant descriptions of other embodiments can be referred to.

The above is detailed introduction to the display panels 100 and the display terminals provided by the embodiments of the present disclosure. This article uses specific examples to illustrate the principles and implementation methods of the present disclosure. The description of the above embodiments is only used to help understand the technical solutions and core ideas of the present disclosure. Those of ordinary skill in the art should understand: it is still possible to modify the technical solutions recorded in the foregoing embodiments, or to equivalently replace some of the technical features, and these modifications or substitutions do not cause the essence of the corresponding technical solutions to depart from the scope of the technical solutions of the embodiments of the present disclosure.

What is claimed is:

1. A display panel, comprising:
a substrate; and
a retaining wall, disposed on the substrate, disposed outside a display area of the display panel and surrounding the display area, and comprising:
a first retaining wall layer; and
a second retaining wall layer, stacked on the first retaining wall layer and disposed on a side of the first retaining wall away from the substrate,
wherein an area of an orthographic projection of the second retaining wall layer on the substrate is less than an area of an orthographic projection of the first retaining wall layer on the substrate, and a horizontal distance between a boundary of the second retaining wall layer away from the display area and a boundary of the first retaining wall layer away from the display area is greater than a first threshold.

2. The display panel according to claim 1, wherein the first retaining wall layer is continuously arranged in a direction away from the display area, and the orthographic projection of the second retaining wall layer on the substrate partially overlaps the orthographic projection of the first retaining wall layer on the substrate.

3. The display panel according to claim 2, wherein the orthographic projection of the second retaining wall layer on the substrate is located in a middle area of the orthographic projection of the first retaining wall layer on the substrate.

4. The display panel according to claim 2, wherein the orthographic projection of the second retaining wall layer on the substrate covers part of the orthographic projection of the first retaining wall layer on the substrate close to the display area.

5. The display panel according to claim 4, wherein an orthographic projection of a boundary of the second retaining wall layer away from the display area on the substrate is located in a middle area of the orthographic projection of the first retaining wall layer on the substrate.

6. The display panel according to claim 4, wherein an orthographic projection of a boundary of the second retaining wall layer close to the display area on the substrate covers an orthographic projection of a boundary of the first retaining wall layer close to the display area on the substrate.

7. The display panel according to claim 6, wherein the orthographic projection of the boundary of the second retaining wall layer close to the display area on the substrate is located adjacent to an edge area of the orthographic projection of the first retaining wall layer on the substrate.

8. The display panel according to claim 1, wherein the first retaining wall layer comprises a first retaining wall segment and a second retaining wall segment disposed on a side of the first retaining wall segment away from the display area, a groove is formed between the first retaining wall segment and the second retaining wall segment, and the second retaining wall layer is disposed on the first retaining wall segment and at least partially fills the groove.

9. The display panel according to claim 8, wherein an orthographic projection of a boundary of the second retaining wall layer away from the display area is located in the groove.

10. The display panel according to claim 8, wherein the second retaining wall layer completely covers the first retaining wall segment.

11. The display panel according to claim 10, wherein an orthographic projection of the first retaining wall segment on the substrate is located in the orthographic projection of the second retaining wall layer on the substrate.

12. The display panel according to claim 8, wherein the orthographic projection of the second retaining wall layer on the substrate partially overlaps an orthographic projection of the first retaining wall segment on the substrate.

13. The display panel according to claim 12, wherein a horizontal distance between a boundary of the second retaining wall layer close to the display area and a boundary of the first retaining wall segment close to the display area is greater than the first threshold.

14. The display panel according to claim 13, wherein an orthographic projection of the boundary of the second retaining wall layer close to the display area on the substrate is located in a middle area of the orthographic projection of the first retaining wall segment on the substrate.

15. The display panel according to claim 8, wherein in a direction parallel to the substrate in a cross-sectional view of the retaining wall, a width of the first retaining wall layer is greater than a width of the second retaining wall layer.

16. The display panel according to claim 1, wherein a value of the first threshold is 8.5 microns.

17. The display panel according to claim 1, wherein in the direction perpendicular to the substrate, a maximum thickness of the first retaining wall layer is greater than a maximum thickness of the second retaining wall layer.

18. The display panel according to claim 1, further comprising:
a display layer, disposed on the substrate and in the display area; and
an organic encapsulation layer, stacked on the display layer and disposed on a side of the retaining wall close to the display area,
wherein, in a direction perpendicular to the substrate, a thickness of an end of the organic encapsulation layer close to the retaining wall is less than a thickness of the retaining wall.

19. A display panel, comprising:
a substrate; and
a plurality of retaining walls, disposed on the substrate and outside a display area of the display panel, spaced apart to form a plurality of closed loops each surrounding the display area, and each of the retaining walls comprising:
a first retaining wall layer; and
a second retaining wall layer, stacked on the first retaining wall layer and disposed on a side of the first retaining wall away from the substrate,
wherein an area of an orthographic projection of the second retaining wall layer on the substrate is less than an area of an orthographic projection of the first retaining wall layer on the substrate, and a horizontal distance between a boundary of the second retaining wall layer away from the display area and a boundary of the first retaining wall layer away from the display area is greater than a first threshold.

20. A display terminal, comprising a display panel, and the display panel comprising:
a substrate; and
a plurality of retaining walls, disposed on the substrate, disposed outside a display area of the display panel, spaced apart to form a plurality of closed loops surrounding the display area, and each comprising:
a first retaining wall layer; and
a second retaining wall layer, stacked on the first retaining wall layer and disposed on a side of the first retaining wall away from the substrate,
wherein an area of an orthographic projection of the second retaining wall layer on the substrate is less than an area of an orthographic projection of the first retaining wall layer on the substrate, and a horizontal distance between a boundary of the second retaining wall layer away from the display area and a boundary of the first retaining wall layer away from the display area is greater than a first threshold.
